(19) United States
(12) Patent Application Publication
(10) Pub. No.: US 2010/0084748 A1
(43) Pub. Date: Apr. 8, 2010

(54) THIN FOIL FOR USE IN PACKAGING INTEGRATED CIRCUITS

(75) Inventors: Anindya PODDAR, Sunnyvale, CA (US); Jaime A. BAYAN, San Francisco, CA (US); Nghia Thuc TU, San Jose, CA (US); Will K. WONG, Belmont, CA (US); Ken PHAM, San Jose, CA (US)

Correspondence Address: Beyer Law Group LLP/ NSC, P.O.Box 1687, Cupertino, CA, 95015-1687, US

(73) Assignee: NATIONAL SEMICONDUCTOR CORPORATION, Santa Clara, CA (US)

(21) Appl. No.: 12/633,703

(22) Filed: Dec. 8, 2009

Related U.S. Application Data
(63) Continuation-in-part of application No. 12/133,335, filed on Jun. 4, 2008.

(51) Int. Cl. H01L 23/48; B32B 15/04; B32B 3/00; B23K 1/06; H01L 21/50

(52) U.S. Cl. 257/666; 428/457; 428/172; 228/111.5; 438/112; 257/E21.499; 257/E23.01

(57) ABSTRACT

Methods for minimizing warpage of a welded foil carrier structure used in the packaging of integrated circuits are described. Portions of a metallic foil are ultrasonically welded to a carrier to form a foil carrier structure. The ultrasonic welding helps define a panel in the metallic foil that is suitable for packaging integrated circuits. Warpage of the thin foil can be limited in various ways. By way of example, an intermittent welding pattern that extends along the edges of the panel may be formed. Slots may be cut to define sections in the foil carrier structure. Materials for the metallic foil and the carrier may be selected to have similar coefficients of thermal expansion. An appropriate thickness for the metallic foil and the carrier may be selected, such that the warpage of the welded foil carrier structure is limited when the foil carrier structure is subjected to large increases in temperature. Foil carrier structures for use in the above methods are also described.

### CROSS-REFERENCE TO RELATED APPLICATIONS

This application is a Continuation-in-Part of and claims priority to U.S. patent application Ser. No. 12/133,335, entitled “Foil Based Semiconductor Package,” filed Jun. 4, 2008, which is hereby incorporated by reference in its entirety for all purposes.

### TECHNICAL FIELD

The present invention relates generally to the packaging of integrated circuits. More particularly, the present invention relates to packaging methods and arrangements involving thin foils.

### BACKGROUND OF THE INVENTION

There are a number of conventional processes for packaging integrated circuit (IC) dice. By way of example, many IC packages utilize a metallic leadframe that has been stamped or etched from a metal sheet to provide electrical interconnects to external devices. The die may be electrically connected to the leadframe by means of bonding wires, solder bumps or other suitable electrical connections. In general, the die and portions of the leadframe are encapsulated with a molding material to protect the delicate electrical components on the active side of the die while leaving selected portions of the leadframe exposed to facilitate electrical connections to external devices.

Many conventional leadframes have a thickness of approximately 4-8 mils. Further reducing the thickness of the leadframe offers several benefits, including the potential of reducing the overall package size and conserving leadframe metal. In general, however, a thinner leadframe has a greater propensity to warp during the packaging process. A supporting structure, such as backing tape, may be applied to the leadframe to reduce the risk of warpage. Such structures, however, may entail higher costs.

At various times, package designs have been proposed that utilize a metal foil as the electrical interconnect structure in place of the leadframe. Although a number of foil based designs have been developed, none have achieved widespread acceptance in the industry in part because foil based packaging processes tend to be more expensive than conventional leadframe packaging and in part because much of the existing packaging equipment is not well suited for use with such foil based package designs.

Although existing techniques for fabricating leadframes and for packaging integrated circuits using leadframe technology work well, there are continuing efforts to develop even more efficient designs and methods for packaging integrated circuits.

### SUMMARY OF THE INVENTION

In one aspect of the present invention, methods for minimizing warpage in a thin foil used in integrated circuit packaging are described. Portions of a metallic foil are ultrasonically welded to a carrier to form a foil carrier structure. The ultrasonic welding helps define a panel in the metallic foil that is suitable for packaging integrated circuits. One embodiment of the present invention involves forming an intermittent welding pattern that extends along the edges of the panel. In another implementation, notches and/or slots are cut in the foil carrier structure. In still another embodiment of the present invention, the materials for the metallic foil and the carrier are selected to have similar coefficients of thermal expansion. Additionally, the thicknesses of the metallic foil and the carrier may be selectively correlated to reduce heat-induced warpage in the foil.

In another aspect of the present invention, foil carrier structures for use in the aforementioned methods are described.

### BRIEF DESCRIPTION OF THE DRAWINGS

The invention and the advantages thereof, may best be understood by reference to the following description taken in conjunction with the accompanying drawings in which:

FIG. 1A is a diagrammatic top view of a foil carrier panel with an intermittent welding pattern according to one embodiment of the present invention.

FIG. 1B is a diagrammatic top view of a foil carrier panel with slots and notches according to one embodiment of the present invention.

FIG. 1C is a diagrammatic side view of a foil carrier panel according to one embodiment of the present invention.

FIG. 2 is a flow chart illustrating a process for packaging an integrated circuit device in accordance with one embodiment of the present invention.

FIGS. 3A-3E are diagrammatic side views of various stages of the packaging process in accordance with one embodiment of the present invention.

FIG. 4A is a diagrammatic top view of an example etching carrier after the molded foil structure illustrated in FIG. 3E has been placed in the carrier.

FIG. 4B is a diagrammatic top view of the etching carrier and molded foil structure illustrated in FIG. 4A after etching.

FIG. 4C is an enlarged diagrammatic top view of a device area resulting from the etching process of FIG. 4B according to one embodiment of the present invention.

FIGS. 5A-5C are diagrammatic side views of the molded foil structure illustrated in FIG. 3D after etching, electroplating and singulation.

FIG. 5D is a diagrammatic side view of a singulated package according to one embodiment of the present invention.

FIG. 5E is a diagrammatic bottom view of the singulated package illustrated in FIG. 5D.

FIGS. 6A and 6B are diagrammatic side and top views of a metallic foil and a carrier being unwound from coils according to one embodiment of the present invention.

FIG. 6C is a diagrammatic top view of a foil carrier panel arrangement according to one embodiment of the present invention.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of integrated circuits using thin foils. Various approaches for incorporating thin foils into integrated circuit packaging involve welding a thin foil to a carrier to form a foil carrier structure. At various stages in the packaging and assembly process (e.g., die attach cure, wire bonding, molding, etc.), the foil carrier structure is subjected to high temperatures. Generally, since the carrier and the foil are welded together, temperature cycling can cause frame warpage due to the CTE mismatch between the carrier and the foil, which may cause problems during package assembly and degrade the performance and reliability of the resulting integrated circuit package. Although pressure can be applied to the thin foil to arrest warpage, this generally requires additional process steps and/or materials. Accordingly, the present invention pertains to arrangements and methods for reducing warpage while minimizing or eliminating the need for applying such pressure to the foil.

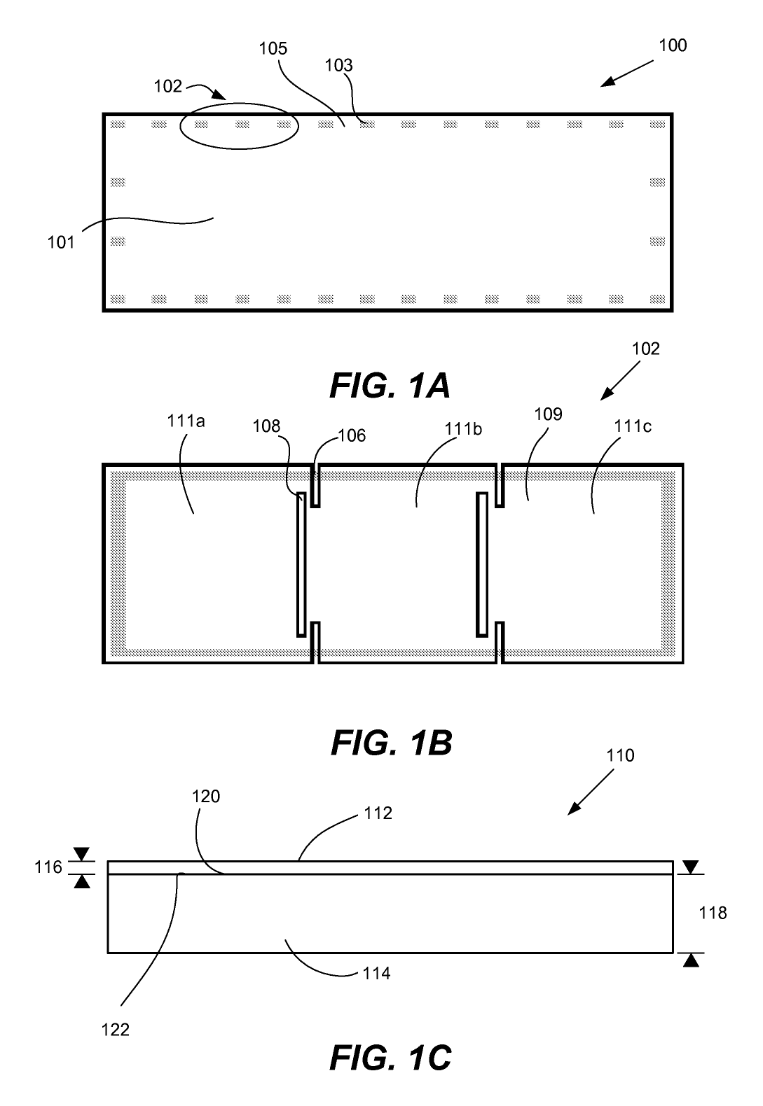

Referring now to FIGS. 1A-1C, exemplary foil carrier panels for use in IC packaging are described. FIG. 1A illustrates a diagrammatic top view of a foil carrier panel 100 according to one embodiment of the present invention. A metallic foil 101 is ultrasonically bonded to an underlying carrier (not shown) using an intermittent welding pattern 102. The intermittent welding pattern 102 intersperses bonded portions 103 with unbonded portions 105.

Generally, if the metallic foil 101 and the underlying carrier have substantially different coefficients of thermal expansion (CTE), they will expand at different rates when subjected to an increase in temperature. The difference in the rates of expansion can cause tension at bonded portions 103. The intermittent welding pattern 102, however, provides stress relief by allowing expansion at the unbonded portions 105. As a result, the overall warpage of the metallic foil is reduced.

The intermittent welding pattern 102 may be arranged in any appropriate manner, as long as each bonded portion 103 is adjacent to and/or surrounded by the unbonded portions 102. By way of example, bonded portions 103 with a pitch of between approximately 10 and 20 mm works well in various applications, although larger and smaller pitches are also possible. (Pitch can be understood as the distance between the centers of adjacent pairs of bonded portions 103.) In some embodiments, the length of the unbonded portion 105 that separates two adjacent bonded portions 103 may be approximately between 10 and 20 mm and the length of each bonded portion 103 may be between 3 and 7 mm. Preferably, multiple bonded portions 103 are arranged with a substantially uniform pitch in lines along all four edges of the rectangular foil carrier panel 100. Such an arrangement helps secure all 4 sides of the foil carrier panel 100 and helps distribute tension uniformly around the periphery of the panel.

Referring next to FIG. 1B, a foil carrier panel 102 in accordance with another embodiment of the present invention will be described. Slots 108 and notches 106 have been cut in the foil carrier panel 102, which includes a metallic foil 109 that has been ultrasonically welded to an underlying carrier (not shown) using continuous welding lines 104. In the illustrated embodiment, the slots 108 and notches 106 penetrate entirely through the foil 109 and the underlying carrier, although this is not a requirement.

The formation of slots 108 and notches 106 in the foil carrier panel 102 are another means of reducing the warpage of the foil carrier panel 102. Generally, when an uncut foil carrier panel is subjected to high temperatures, expansion occurs along the entire length of the panel. In the illustrated embodiment, the slots 108, which extend across the majority of the width of the foil carrier panel 102 and are arranged in the middle of the panel, effectively divide the foil carrier panel 102 into sections 111 and helps limit expansion to each section. The notches 106, which extend into the foil carrier panel 102 from its edges, provide stress relief by breaking up the welding lines 104.

Warpage reduction can also be achieved by adjusting the thickness of the thin foil relative to its underlying carrier. This approach will be discussed with reference to FIG. 1C, which is a diagrammatic side view of a foil carrier panel 110. Foil carrier 110 includes a thin foil 112 with a thickness 116 that is ultrasonically bonded to a carrier 114 with a thickness 118. Generally, the exterior surface of thinner layers, when subjected to an increase in temperature, expand faster than the exterior surface of thicker layers. By taking into account the CTEs of the foil 112 and carrier 114 and adjusting their thicknesses 116 and 118 accordingly, the mismatch in the rate of expansion between the foil surface 120 and the carrier surface 122 can be reduced. As a result, the foil surface 120 is not pulled and warped as much by its bonding to the carrier surface 122.

Various tests have been performed to help confirm the efficacy of the aforementioned approaches. In one experiment, a foil carrier panel was used that was formed by ultrasonically welding a copper foil to an aluminum carrier with a single, continuous welding line that extended along the periphery of the panel. The foil carrier panel had dimensions of approximately 165×65 mm. The copper foil had a thickness of approximately 18 microns. The aluminum carrier had a thickness of approximately 7 mils. The foil carrier panel was subjected to a temperature increase from room temperature to approximately 175° C. The resulting warpage of the foil carrier panel was approximately 30 mm. (For the purposes of this experiment, the warpage of the foil carrier panel is understood as the maximum linear displacement of the foil carrier panel as a result of the temperature increase, as measured along an axis that is perpendicular to the foil and carrier surfaces.) The same test conditions were repeated in a second experiment, except that the thickness of the aluminum carrier was changed to approximately 20 mm and the foil was ultrasonically welded to the carrier using a stitched, intermittent bonding pattern. The warpage of the foil carrier panel in the second experiment was approximately 3 mm, which constitutes a 10 fold decrease in warpage. More generally, when a foil carrier structure having appropriately calibrated foil and carrier thicknesses and a surface area of at least 7500 mm² is subjected to a temperature increase in excess of approximately 150° C., the warpage of the foil carrier structure may be limited to approximately 5 mm or less. Aside from the pressure exerted upon the foil by the ultrasonic bonding, this result can be achieved without applying substantial additional pressure on the foil and/or carrier surface (e.g., without applying a tape to the foil, without having the semiconductor processing equipment apply pressure on the foil surface to suppress warpage, etc.)

Warpage can also be addressed by selecting materials for the foil 112 and the carrier 114 that are suitable for integrated circuit packaging and that have similar CTEs. By way of example, a foil and carrier that have CTEs at 20° C. that differ by less than 10⁻⁶/C work well for various applications. Accordingly, a suitable pairing would be a foil 112 made of copper and a carrier 114 made of Aluminum CE17. The two materials are suitable for use in foil-based integrated circuit packages and both have CTEs of approximately 18.

It should be appreciated that any of the various approaches discussed above in connection with FIGS. 1A-1C can be combined or modified, depending on the needs of a particular application. By way of example, another embodiment of the present invention is a foil carrier panel with both an intermittent welding pattern (as shown in FIG. 1A) and slots (as shown in FIG. 1B). Various implementations involve intermittent welding patterns, slots and notches that differ in quantity, orientation, size and/or shape from those depicted in FIGS. 1A-1C.

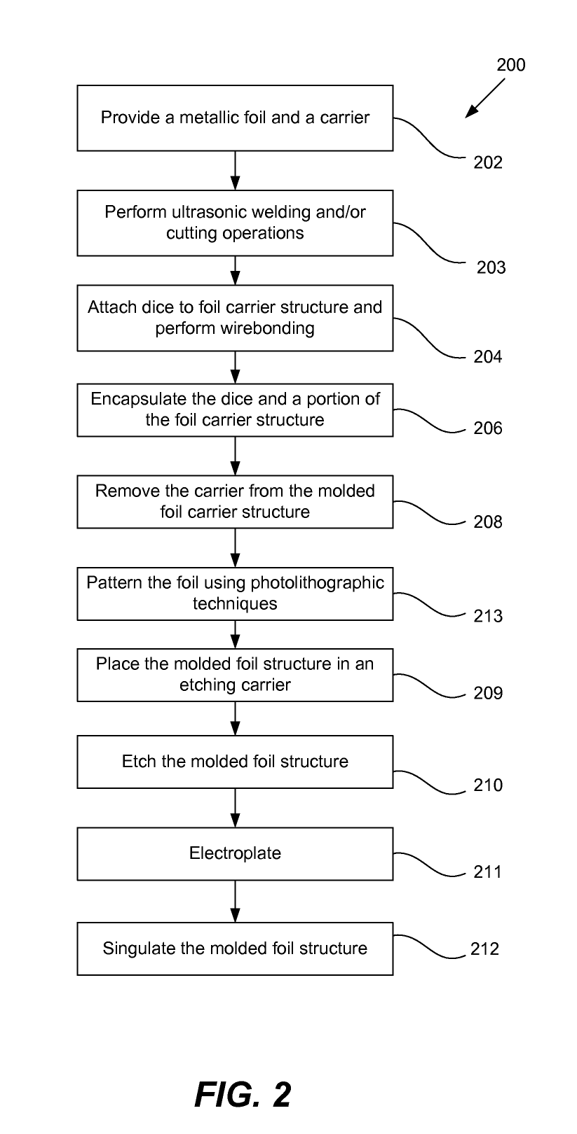

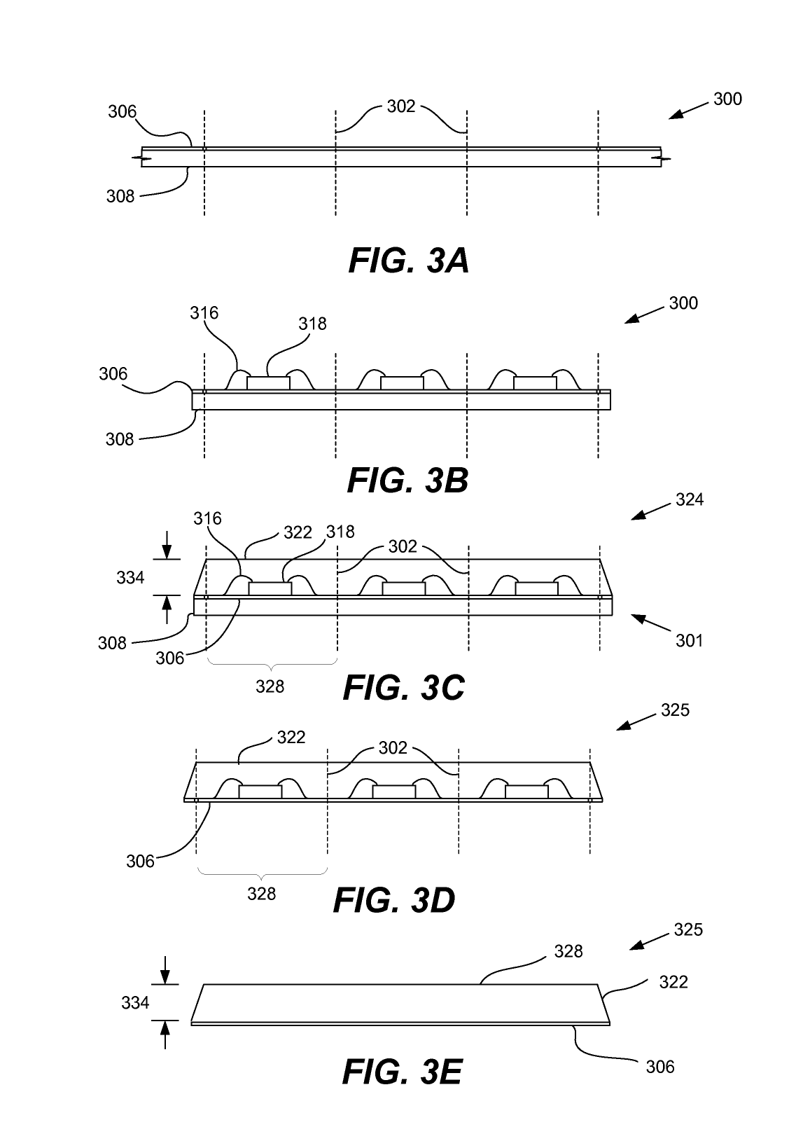

Referring next to FIGS. 2-5, a method 200 of forming integrated circuit packages using the thin foil arrangements illustrated in FIG. 1 will be described. Initially, in step 202, a foil 306 and a carrier 308 of FIG. 3A is provided. In some embodiments, the foil 306 is made of copper and the carrier 308 is made of aluminum, although the foil 306 and the carrier 308 can be made of other suitable materials as well. For example, the foil 306 can include multiple layers and/or metals, such as copper, nickel, and palladium. Carrier 308 can be made of any suitable material e.g., stainless steel, steel, plastic, FR4, etc. Various implementations use a foil 306 having a thickness between 8 and 35 microns and/or a carrier having a thickness between 7 and 25 mils.

Afterward, the foil 306 is ultrasonically bonded with the carrier 308 to form a foil carrier structure 300 (step 203 of FIG. 2). The ultrasonic bonding may be performed to form any of the welding arrangements discussed above in connection with FIG. 1 (e.g., continuous welding lines, intermittent welding patterns, etc.) Ultrasonic bonding offers the benefit of being strong enough to endure stresses imposed by later stages of the packaging process while still allowing the carrier to be easily separated from the foil after dice and molding material have been added to the foil. The term ultrasonic bonding, as used herein, includes any suitable bonding technique having an ultrasonic component, including thermosonic bonding. Although ultrasonic bonding works well, it should be appreciated that other suitable bonding techniques may be used to secure the foil to the carrier. By way of example, a variety of suitable adhesives or tape may be used. Various approaches to ultrasonically welding and forming the foil carrier structure 300 are discussed in U.S. patent application Ser. No. 12/133,335, entitled “Foil Based Semiconductor Package,” filed Jun. 4, 2008, which is hereby incorporated by reference in its entirety for all purposes.

Preferably after ultrasonic bonding, the foil carrier structure 300 may be optionally cut to form one or more of the slots and/or notches discussed above in connection with FIG. 1B (step 203 of FIG. 2). Generally, the ultrasonic bonding helps maintain the alignment of the foil 306 and the carrier 308 during the cutting operation. In some embodiments, the cutting operation may also take place before and/or substantially at the same time as the ultrasonic bonding.

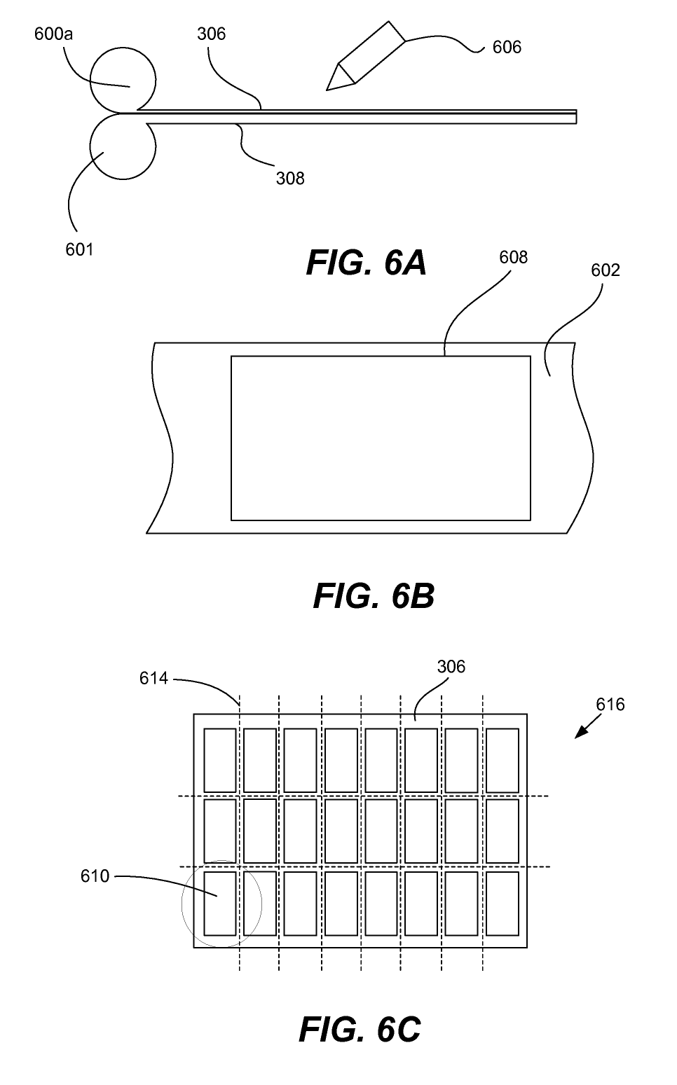

As a result of the aforementioned ultrasonic bonding and/or cutting operations, one or more foil carrier panels of FIGS. 1A, 1B and/or 1C are formed in the foil carrier structure 300 of FIG. 3A. The foil carrier structure 300 may be arranged in any suitable manner. By way of example, the foil carrier structure 300 may be formed from strips that are unwound from coils and subsequently welded together. In still another embodiment, the foil carrier structure 300 is a rectangular panel arrangement that includes multiple foil carrier panels. (These implementations are discussed later in connection with FIGS. 6A-6C.)

Referring now to step 204 of FIG. 2 and FIG. 3B, dice 318 are attached to the foil carrier structure 300 using conventional die attach techniques. In the illustrated embodiment, the dice 318 are attached to the foil 306 using conventional die attach material and further attached to the foil 306 with conventional wire bonds 316, although any suitable electrical connection (e.g., solder bumps in a flip chip-style arrangement, etc.) may be used. Although FIG. 3B shows the foil carrier structure supporting only several dice 318, it should be appreciated that the foil carrier structure 300 can be sized and arranged to support hundreds of dice or more.

In step 206 and FIG. 3C, dice 318 and at least a portion of the top surface of the foil 306 are encapsulated with a molding material 322, forming molded foil carrier structure 324. In the illustrated embodiment of FIG. 3C, molding material 322 is added in a single continuous strip. That is, the molding material has been relatively evenly applied across the molded portions of foil 306. It is noted that this type of molding is not common in leadframe based packaging. Rather, the devices carried on leadframe strips are typically molded either individually or in sub-panels. The benefits of a continuous strip of molding material will be discussed in connection with FIGS. 3D, 3E and step 208.

In step 208, the carrier portion of molded foil carrier structure 324 of FIG. 3C is removed, resulting in molded foil structure 325 of FIG. 3D. At this point the molding material 322 provides structural support for the foil in place of the carrier 308. It should be appreciated that an advantage of the continuous strip molding approach is that it provides good support for the entire panel so that the strip may still be handled in panel form. In contrast, if molding gaps are provided between subpanels during the molding operation, then the subpanels would need to be handled independently after removal of the carrier.

FIG. 3E presents an external view of molded foil structure 325. It should be appreciated that although the top surface 328 of molded foil structure 325 is substantially planar, this is not a requirement. Molding material 322 in molded foil structure 325 may assume a variety of patterns and shapes, and the depth 334 of molding material 322 may vary along the length of molded foil structure 325.

Referring to step 213 of FIG. 2, the exposed foil 306 of the molded foil structure 325 of FIG. 3E is then patterned using known photolithographic techniques. In various embodiments, a photoresist layer is applied over the foil 306. Portions of the photoresist layer are selectively exposed to light. A developer solution is then applied to remove portions of the photoresist layer to form a desired pattern. A wide variety of approaches known to persons of ordinary skill in the art can be used to pattern the exposed foil 306.

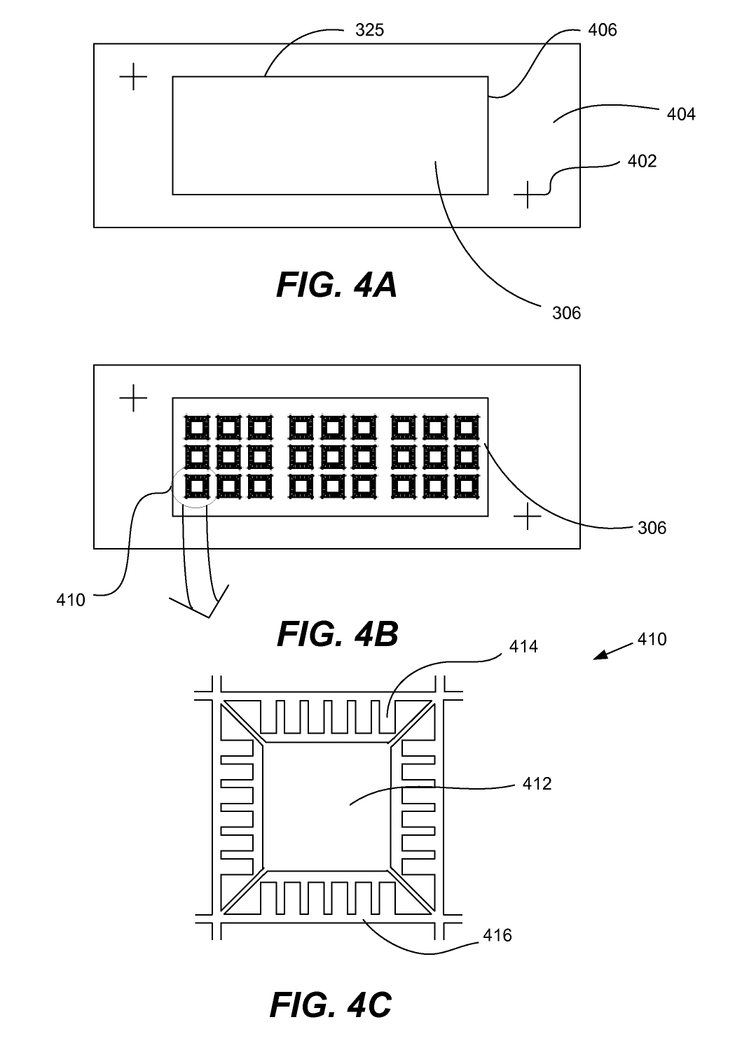

In optional step 209, molded foil structure 325 is placed in etching carrier 404 as illustrated in FIGS. 4A and 4B. It should be noted that the use of the etching carrier 404 is not required and the molded foil structure 325 can be etched using any suitable device or process e.g., an etching conveyor, etc. FIG. 4A illustrates a top view of etching carrier 404 containing molded foil structure 325. In the illustrated embodiment, etching carrier 404 includes alignment holes 402 and a cavity 406 configured to receive molded foil structure 325. Etching carrier 404 is designed to receive molded foil structure 325 of FIG. 3E such that the top surface 328 of the molded foil structure is hidden within cavity 406 and foil 306 is exposed. The etching carrier may be reusable and can be made of various materials, such as fiber glass.

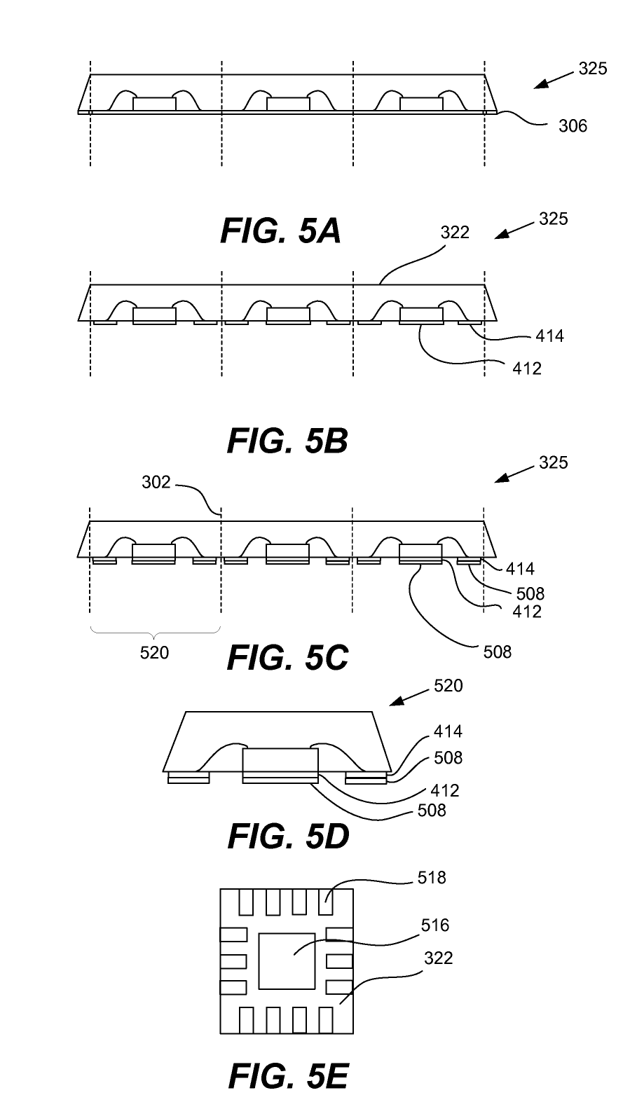

In step 210, foil 306 is etched using any suitable technique known to persons of ordinary skill in the art, such as chemical etching. As shown in FIGS. 4B, 5A and 5B, the etching removes portions of foil 306 and defines multiple device areas 410. Each device area 410 is arranged to support one or more of the dice 318 of FIG. 3.

Some embodiments involve forming device areas 410 with bus bars in order to facilitate the later electroplating of a metal, such as tin or solder, on electrical contacts formed from the foil. FIG. 4C diagrammatically illustrates such a device area. In the illustrated embodiment, device area 410 has a die attach pad 412, contact leads 414 and bus bars 416. Bus bars 416 electrically connect the pad and leads. Bus bars 416 may also form conductive links between multiple device areas. It should be appreciated that device area 410 represents only one of many possible arrangements.

FIGS. 5A-5B provide a diagrammatic side view of the effect of the etching process on molded foil structure 325. FIG. 5A is a diagrammatic side view of molded foil structure 325 prior to etching. FIG. 5B illustrates how the etching process removes portions of foil 306, reveals sections of molding material 322 and forms contact leads 414 and die attach pad 412.

As discussed above, some embodiments contemplate step 211 of FIG. 2, which involves the electroplating of solder 508 of FIG. 5C onto die attach pad 412 and contact leads 414. In step 212, the molded foil structure 325 is singulated along projected saw streets 302 of FIG. 5C to form semiconductor packages. Molded foil structure 325 may be singulated using a variety of techniques, including sawing and laser cutting. An enlarged side view of singulated package 520 is illustrated in FIG. 5D. A diagrammatic bottom view of the package is shown in FIG. 5E. The bottom view illustrates die attach pad 516 and contact leads 518 surrounded by molding material 322.

The processes described above in connection with FIGS. 3-5 can be modified as appropriate for particular applications. By way of example, application Ser. No. 12/571,202, entitled “Foil Based Semiconductor Package,” filed Sep. 30, 2009 by the assignee of the present application, which is hereby incorporated by reference in its entirety for all purposes, describes various die attach, etching and processing steps for thin foils. More particularly, the '202 application generally relates to attaching dice to a thin foil in a flip chip arrangement, etching the thin foil to form device areas, and selectively applying a dielectric material over portions of each device area. Any of the operations described in the '202 application can be combined with and/or replace the operations described above.

Referring next to FIGS. 6A and 6B, additional arrangements and methods for forming the foil carrier structure 300 of FIG. 3A will be described. FIGS. 6A and 6B illustrate diagrammatic side and top views of a foil coil 600 and a carrier coil 601 according to one embodiment of the present invention. As seen in FIG. 6A, a metallic foil 306 is unwound from the foil coil 600 while the carrier 308 is unwound from the carrier coil 601. Initially, unwound sections of the foil 306 and the carrier 308 may be cleaned by conveying them past one or more optional cleaning stations (not shown), which apply cleaning solutions to the foil and the carrier. A welding device 606 (e.g., an ultrasonic horn, etc.) then ultrasonically welds the superimposed foil 306 and carrier 308 to form any of the welding patterns discussed in connection with FIGS. 1A-1C. Afterward, the welded sections may be passed by additional cleaning stations and/or subjected to a first set of cutting operations, which may form any of the slots and/or notches discussed in connection with FIG. 1B. As seen in FIG. 6B, the welding and/or cutting operations form one or more foil carrier panels 608, which each have various features discussed in connection with foil carrier panels 100, 102 and/or 110 of FIG. 1. Preferably, the above welding and cutting operations take place while sections of the foil 306 and the carrier 308 are in motion and being unwound from the foil coil 600 and the carrier coil 601 (although this is not a requirement). Such an approach can help streamline package assembly and reduce the number of processing steps. A second set of optional cutting operations may then be performed to form appropriately sized foil carrier structures. Afterward, the die attach, encapsulation, etching and/or singulation steps described in connection with FIGS. 3B-3E, 4 and 5 can be applied to the resulting foil carrier structure(s).

Referring now to FIG. 6C, another approach for forming the foil carrier structure 300 of FIG. 3A is described. FIG. 6C is a diagrammatic top view of a foil carrier panel arrangement 616 according to another embodiment of the present invention. A metallic foil 306 is ultrasonically bonded to an underlying carrier (not shown). The ultrasonic bonding defines multiple foil carrier panels 610. Welding and/or cutting operations can be performed on the foil carrier structure 300 to form multiple panels 610 that each have intermittent welding patterns, slots, notches and/or any other feature described in connection with the panels illustrated in FIG. 1. Afterward, the foil carrier structure 300 may be optionally cut along projected saw streets 614 as appropriate. Die attach, encapsulation, etching and/or singulation steps described in connection with FIGS. 3B-3E, 4 and 5 can each be applied on the level of an individual panel 610 or on the level of an entire panel arrangement 616.

Although only a few embodiments of the invention have been described in detail, it should be appreciated that the invention may be implemented in many other forms without departing from the spirit or scope of the invention. By way of example, FIG. 1B depicts two slots 108 of FIG. 1B, which each extend across a majority of the width of the panel 102. The present invention also contemplates fewer or more slots per panel and slots that each have different dimensions relative to the width of the panel. Although FIG. 1B illustrates only 4 notches that are positioned near the 4 ends of the slots 108, there may also be fewer or more notches in a different arrangement. FIG. 1A has bonded portions 102 that are linearly arranged and rectangular. The long sides of all of the rectangular bonded portions 102 run parallel to the long sides of the rectangular panel 100. In various embodiments, the bonded portions 102 may be oriented vertically rather than horizontally, have different shapes and/or be arranged in a different layout. It should be further appreciated that the steps of FIG. 2, while illustrated in a specific order, may be reordered as appropriate. Additionally, one or more steps may be replaced and/or eliminated for particular applications. Therefore, the present embodiments should be considered as illustrative and not restrictive and the invention is not limited to the details given herein, but may be modified within the scope and equivalents of the appended claims.

What is claimed is:

1. A method for packaging integrated circuits, comprising:
providing a carrier;
providing a metallic foil; and
ultrasonically welding selected portions of the metallic foil to the carrier to form a foil carrier structure, the ultrasonic welding helping to define a panel in the metallic foil that is suitable for use in packaging integrated circuits.

2. The method of claim 1, wherein the ultrasonic welding forms an intermittent welding pattern that extends along edges of the panel, the intermittent welding pattern including ultrasonically bonded portions of the metallic foil interspersed among unbonded portions of the metallic foil, the unbonded portions being portions of the metallic foil that have not been ultrasonically welded to the carrier.

3. The method of claim 2, further comprising:
attaching a multiplicity of dice to the metallic foil;
encapsulating the multiplicity of dice and at least a portion of the metallic foil with a molding material to form a molded foil carrier structure;
removing the carrier from the molded foil carrier structure to form a molded foil structure;
patterning the exposed foil of the molded foil structure using photolithographic techniques;
etching the metallic foil after the carrier has been removed to define a multiplicity of device areas in the metallic foil, each device area supporting at least one of the multiplicity of dice and having a multiplicity of electrical contacts, wherein the etching exposes portions of the molding material; and
after the etching step, singulating the molded foil structure to form a multiplicity of packaged integrated circuit devices.

4. The method of claim 2, wherein at least a subset of the ultrasonically bonded portions are arranged linearly and have a pitch of approximately between 10 and 20 mm.

5. The method of claim 2, wherein the intermittent welding pattern is arranged into at least four lines of bonded portions, each line of bonded portions including at least two bonded portions that are linearly arranged and separated by unbonded portions, the four lines of bonded portions defining four sides of a rectangular panel in the metallic foil.

6. The method of claim 2, wherein:
the carrier is made of aluminum;
the metallic foil is made of copper; and
the thickness of the metallic foil is between approximately 8 and 35 microns and the thickness of the carrier is between approximately 7 and 25 mils.

7. The method of claim 2, further comprising:
unwinding the carrier from a carrier coil;
unwinding the metallic foil from a foil coil, wherein the ultrasonic bonding is performed while the metallic foil and the carrier are in motion and being unwound from the foil coil and the carrier coil, respectively;
before the ultrasonic welding, conveying portions of the metallic foil and the carrier past a first set of one or more cleaning stations;
at the first set of cleaning stations, applying cleaning solution to clean the metallic foil and the carrier;
after the ultrasonic welding, conveying portions of the metallic foil and the carrier past a second set of one or more cleaning stations; and
at the second set of cleaning stations, applying cleaning solution to clean the metallic foil and the carrier.

8. The method of claim 1, further comprising:
after the ultrasonic welding, cutting the foil carrier structure to form a plurality of slots in the foil carrier structure, each of the plurality of slots penetrating entirely through the metallic foil and the carrier, wherein the plurality of slots are arranged to help divide the foil carrier structure into sections, thereby helping to contain heat expansion within each section and reduce warpage in the foil carrier structure.

9. The method of claim 8, wherein a subset of the slots are arranged in the middle of the panel and extend across at least a majority of the width of the panel.

10. The method of claim 8, wherein each slot of a subset of the slots is a notch at an edge of the panel.

11. The method of claim 10, wherein the ultrasonic welding forms a welding line on the metallic foil that is non-continuous over each slot but is otherwise continuous, the welding line forming a rectangle and extending along the periphery of the panel.

12. The method of claim 1, wherein the metallic foil and the carrier have coefficients of thermal expansion (CTE) at 20° C. that differ by less than 10⁻⁶/C, thereby helping to reduce warpage in the metallic foil and the carrier.

13. The method of claim 12, wherein the metallic foil is made of copper and the carrier is made of aluminum alloy CE17.

14. The method of claim 1, wherein:
the ultrasonic welding involves welding a carrier surface of the carrier to an opposing foil surface of the metallic foil, the carrier surface and the foil surface each having a surface area of at least approximately 7500 mm²; and
subjecting the foil carrier structure to a temperature increase of greater than approximately 150° C. while limiting the warpage of the foil surface to approximately 5 mm or less without applying any substantial pressure external to the foil and the carrier on the carrier surface and the foil surface.

15. The method of claim 14, wherein the thickness of the metallic foil is between approximately 8 and 35 microns and the thickness of the carrier is between approximately 7 and 25 mils.

16. A foil carrier structure for packaging integrated circuits, comprising:
a carrier;
a metallic foil ultrasonically welded to the carrier to form a foil carrier structure, the ultrasonic welding defining a panel in the metallic foil that is suitable for use in packaging integrated circuits.

17. The foil carrier structure of claim 16, wherein the ultrasonic welding forms an intermittent welding pattern that extends along edges of the panel, the intermittent welding pattern including ultrasonically bonded portions of the metallic foil interspersed among unbonded portions of the metallic foil, the unbonded portions being portions of the metallic foil that have not been ultrasonically welded to the carrier.

18. The foil carrier structure of claim 17 further comprising:
a multiplicity of integrated circuit dice mounted onto the metallic foil; and
a molding material that encapsulates the multiplicity of integrated circuit dice and at least portions of the metallic foil.

19. The foil carrier structure of claim 16, wherein the foil carrier structure includes a plurality of slots, each of the plurality of slots penetrating entirely through the metallic foil and the carrier, wherein the plurality of slots are arranged to help divide the foil carrier structure into sections, thereby helping to contain heat expansion within each section and reduce warpage in the foil carrier structure.

20. The foil carrier structure of claim 16, wherein:
the metallic foil includes a foil surface;
the carrier including a carrier surface, the carrier surface being ultrasonically welded to the foil surface, the carrier surface and the foil surface each having a surface area of at least 7500 mm²; and
the metallic foil and the carrier being arranged such that, when the welded foil carrier panel arrangement is subjected to a temperature increase of at least 150° C., the warpage of the foil surface and the carrier surface is limited to 5 mm or less without applying any substantial pressure external to the foil and the carrier on the carrier surface and the foil surface.
